(19) United States
(12) Patent Application Publication
(10) Pub. No.: US 2026/0095178 A1
(43) Pub. Date: Apr. 2, 2026

(54) ADAPTIVE POWER SWITCH

(71) Applicant: APPLE INC., CUPERTINO, CA (US)

(72) Inventors: JELAM K PAREKH, SUNNYVALE, CA (US); MUHAMMAD H. KIANI, LOS ALTOS, CA (US); SAMBASIVAN NARAYAN, SARATOGA, CA (US); MOHAMED H. ABU-RAHMA, MOUNTAIN VIEW, CA (US); JAROSLAV RASZKA, MORGAN HILL, CA (US); DONGKWUN KIM, SANTA CLARA, CA (US); JONGHYUN OH, SANTA CLARA, CA (US); VIVEKANANDAN VENUGOPAL, SARATOGA, CA (US); NEELADRI SAIN, SAN JOSE, CA (US)

(21) Appl. No.: 19/014,884

(22) Filed: Jan. 9, 2025

Related U.S. Application Data
(60) Provisional application No. 63/700,604, filed on Sep. 27, 2024.

(51) Int. Cl. H03K 17/687

(52) U.S. Cl. CPC H03K 17/6872

(57) ABSTRACT

An example apparatus includes a plurality of switch circuit groups. Each switch circuit group includes a primary power switch circuit and a set of secondary power switch circuits. The apparatus includes a connection circuit that is configured to receive a first control signal from a control circuit and provide the first control signal to the plurality of switch circuit groups in a serial order. The plurality of switch circuit groups are configured to initialize based on the first control signal. The connection circuit is also configured to receive a second control signal from the control circuit and provide the second control signal in parallel to the switch circuit groups. Selected ones of the switch circuit groups are turned on and unselected ones of the switch circuit groups are turned off based on the second control signal.

### CROSS REFERENCE TO RELATED APPLICATION

This application is a non-provisional utility application for patent entitled to a filing date and claiming the benefit of earlier-filed U.S. Provisional Patent Application No. 63/700,604, filed Sep. 27, 2024, which is hereby incorporated herein by reference in its entirety.

### BACKGROUND

### Technical Field

The embodiments disclosed herein relate to power management and control in an integrated circuit, specifically the use of power switches for power gating.

### Description of the Related Art

Integrated circuits may include multiple circuit blocks designed to perform various functions. For example, an integrated circuit may include a memory circuit block configured to store multiple program instructions, a processor or processor core configured to retrieve the program instructions from the memory and execute the retrieved instructions.

In some integrated circuits, different circuit blocks or different portions of a particular circuit block may operate using different power supply voltage levels. Circuit blocks or portions of circuits blocks operating using a common power supply voltage level may be referred to as being included in a common power domain. In some integrated circuits, the different power supply voltage levels used within the integrated circuits may be generated by a Power Management Unit (commonly referred to as a “PMU”) or other suitable circuits. Such PMUs may include voltage regulator circuits and supporting control circuits configured to generate the desired power supply voltage levels.

During operation of an integrated circuit, some circuit blocks or portions of a particular circuit may be unused for periods of time. To reduce power dissipation of the integrated circuit, the unused circuit blocks or portions of the particular circuit block may be decoupled from the power supply. When it is determined that a currently unused circuit block is to return to an active state, the currently unused circuit block is coupled to the power supply prior to resuming operation. In addition, the amount of power used by a particular circuit block may change over time. For example, a circuit block may need more power/current at a first time and less power/current at a second time.

### SUMMARY OF VARIOUS EMBODIMENTS

Various embodiments of power switch circuits are disclosed. A plurality of power switch circuits may be grouped (e.g., logically and/or physically grouped) into groups of power switch circuits. The groups of power switch circuits may be controlled using various control signals generated by a switch control circuit. Based on the control signals, the power switch circuits may operate in different modes (e.g., a voltage regulation mode, an emergency mode, a reduced power mode, etc.).

An example of the present disclosure is directed to an apparatus that includes a plurality of switch circuit groups. Each switch circuit group includes a primary power switch circuit and a set of secondary power switch circuits. The apparatus includes a connection circuit coupled to the plurality of switch circuit groups. The connection circuit is configured to receive a first control signal from a control circuit and provide the first control signal to the plurality of switch circuit groups in a serial order, wherein the plurality of switch circuit groups are configured to initialize based on the first control signal. The connection circuit is configured to receive a second control signal from the control circuit and provide the second control signal in parallel to the switch circuit groups, wherein selected ones of the switch circuit groups are concurrently turned on and unselected ones of the switch circuit groups are concurrently turned off based on the second control signal to generate a regulated output voltage.

### BRIEF DESCRIPTION OF THE DRAWINGS

The following detailed description makes reference to the accompanying drawings, which are now briefly described.

FIG. 1 illustrates a diagram of an example system, in accordance with one or more embodiments of the present disclosure.

FIG. 2 illustrates a diagram of an example switch control circuit, in accordance with one or more embodiments of the present disclosure.

FIG. 3 illustrates a diagram of example switch circuit groups, in accordance with one or more embodiments of the present disclosure.

FIG. 4 illustrates an example primary switch circuit, in accordance with one or more embodiments of the present disclosure.

FIG. 5 illustrates an example secondary switch circuit, in accordance with one or more embodiments of the present disclosure.

FIG. 6 illustrates a flow diagram depicting an embodiment of a method for operating one or more switch circuits, in accordance with one or more embodiments of the present disclosure.

FIG. 7 illustrates a block diagram of an example system, in accordance with one or more embodiments of the present disclosure.

While the disclosure is susceptible to various modifications and alternative forms, specific embodiments thereof are shown by way of example in the drawings and will herein be described in detail. It should be understood, however, that the drawings and detailed description thereto are not intended to limit the disclosure to the particular form illustrated, but on the contrary, the intention is to cover all modifications, equivalents and alternatives falling within the spirit and scope of the present disclosure as defined by the appended claims. The headings used herein are for organizational purposes only and are not meant to be used to limit the scope of the description. As used throughout this application, the word “may” is used in a permissive sense (i.e., meaning having the potential to), rather than the mandatory sense (i.e., meaning must). Similarly, the words “include,” “including,” and “includes” mean including, but not limited to.

### DETAILED DESCRIPTION OF EMBODIMENTS

In some computing systems, to manage power consumption, circuit blocks may be selected to be de-powered for periods of time. When a particular circuit block has been selected to be de-powered, it may be decoupled from a power supply by opening or turning off one or more power switches. If the computing system determines the particular circuit block is needed to perform a desired function or execute desired operations, the one or more power switches may be closed or turned on to couple the particular circuit block back to the power supply.

When power switches are open or turned off, a leakage current may flow through the power switch. Such leakage current is undesirable as it contributes to overall power consumption and, in mobile computing applications, can reduce battery life.

In addition, since the power switch devices may be coupled to a common control signal, an accumulated voltage drop across the common control signal may result in some control terminals (or “gates”) of corresponding power switch devices having an insufficient voltage level necessary to enable the power switches. Additionally, activating power switch circuits using a common control signal can result in too many power switch devices activating within a particular period of time, resulting in high in-rush currents as a circuit block returns to an active state.

Furthermore, the amount of power, current and/or voltage requested by a circuit block may change, fluctuate, etc., as the circuit block operates. If the power switch devices do not provide enough power, current, and/or voltage, the circuit block may malfunction or may not operate properly. If the switch devices provide too much power, current, and/or voltage, the power switch devices may not operate efficiently (e.g., may waste power).

The embodiments illustrated in the drawings and described below may provide techniques for operating power switches while reducing the leakage current through the power switches, thereby reducing overall power consumption. The embodiments illustrated in the drawings and described below may also provide techniques for using power switch circuits that allow for selective enabling and disabling of certain power switch circuits, remediation of the voltage drop of the power switch device control signal, and sequential enabling of power switch circuits to eliminate potential high in-rush currents. The embodiments illustrated in the drawings and described below may further provide techniques to dynamically or adaptively adjust the number of power switch circuits that are turned on/off to satisfy the power/current and/or voltage requested by a circuit block.

An example of the present disclosure is directed to an apparatus. The apparatus includes a plurality of switch circuit groups. Each switch circuit group comprises a primary power switch circuit and a set of secondary power switch circuits. The apparatus includes a connection circuit coupled to the plurality of switch circuit groups. The connection circuit is configured to: receive a first control signal from a control circuit and provide the first control signal to the plurality of switch circuit groups in a serial order, where the plurality of switch circuit groups are configured to initialize based on the first control signal; and receive a second control signal from the control circuit and provide the second control signal in parallel to the switch circuit groups, wherein selected ones of the switch circuit groups are concurrently turned on and unselected ones of the switch circuit groups are concurrently turned off based on the second control signal to generate a regulated output voltage.

In some examples of the apparatus, the connection circuit is further configured to receive a third control signal from the control circuit and provide the third control signal to the plurality of switch circuit groups in parallel, where the plurality of switch circuit groups are all concurrently turned on based on the third control signal. In some examples of the apparatus, the connection circuit is further configured to receive a fourth control signal from the control circuit and provide the fourth control signal to the plurality of switch circuit groups, where an amount of current leakage through the plurality of switch circuit groups is reduced based on the fourth control signal.

In some examples of the apparatus, each primary power switch circuit includes a first power switch coupled to an input power supply signal and an output power supply signal. Each primary power switch circuit further includes a first set of devices configured to: turn on the first power switch in response to the first control signal; provide the first control signal to a next secondary power switch circuit; turn on or turn off the first power switch based on the second control signal; and provide the second control signal to the next secondary power switch circuit.

In some examples of the apparatus, each secondary power switch circuit includes a second power switch coupled to the input power supply signal and the output power supply signal. Each secondary power switch circuit further includes a second set of devices configured to: turn on the second power switch in response to the first control signal; provide the first control signal to a following secondary power switch circuit; turn on or turn off the second power switch based on the second control signal; and provide the second control signal the following secondary power switch circuit.

In some examples of the apparatus, the switch circuit groups are initialized in a serial order and the power switch circuits within each switch circuit group are initialized in a serial order. In some examples, the selected ones of the switch circuit groups vary over time based on a comparison of the regulated output voltage to a target voltage. In some examples, each of the switch circuit groups outputs a substantially different amount of current than other ones of the switch circuit groups. In some examples, the amount of current approximately doubles from each one of the switch circuit groups to a next one of the switch circuit groups.

Another example of the present disclosure is directed to a method, which includes initializing, in response to a first control signal, a plurality of switch circuit groups, where the switch circuit groups are initialized in a serial order, and where each switch circuit group comprises a primary power switch circuit and a set of secondary power switch circuits. The method includes receiving a second control signal in parallel by the switch circuit groups, wherein selected ones of the switch circuit groups are concurrently turned on and unselected ones of the switch circuit groups are concurrently turned off based on the second control signal to generate a regulated output voltage.

Some examples of the method further include receiving a third control signal by the plurality of switch circuit groups in parallel, where the plurality of switch circuit groups are all concurrently turned on based on the third control signal. Some examples of the method further include receiving a fourth control signal by the plurality of switch circuit groups, where an amount of current leakage through the plurality of switch circuit groups is reduced based on the fourth control signal.

In some examples of the method, initializing the plurality of switch circuit groups includes initializing the switch circuit groups in a serial order; and initializing the power switch circuits within each switch circuit group in a serial order. In some examples of the method, the selected ones of the switch circuit groups vary over time based on a comparison of the regulated output voltage to a target voltage.

In some examples of the method, each of the switch circuit groups outputs a substantially different amount of current than other ones of the switch circuit groups. In some examples of the method, the amount of current approximately doubles from each one of the switch circuit groups to a next one of the switch circuit groups.

Another example of the present disclosure is directed to a system, which includes a circuit block and a switch control circuit. The system further includes a plurality of switch circuit groups coupled to the circuit block, where each switch circuit group includes a primary power switch circuit and a set of secondary power switch circuits. The system includes a connection circuit coupled to the switch control circuit and the plurality of switch circuit groups. The connection circuit is configured to: receive a first control signal from the switch control circuit and provide the first control signal to the plurality of switch circuit groups in a serial order, where the plurality of switch circuit groups are configured to initialize based on the first control signal; and receive a second control signal from the switch control circuit and provide the second control signal in parallel to the switch circuit groups, wherein selected ones of the switch circuit groups are concurrently turned on and unselected ones of the switch circuit groups are concurrently turned off based on the second control signal to generate a regulated output voltage for use by the circuit block.

In some examples of the system, the connection circuit is further configured to: receive a third control signal from the switch control circuit and provide the third control signal to the plurality of switch circuit groups in parallel, where the plurality of switch circuit groups are all concurrently turned on based on the third control signal; and receive a fourth control signal from the switch control circuit and provide the fourth control signal to the plurality of switch circuit groups, where an amount of current leakage through the plurality of switch circuit groups is reduced based on the fourth control signal.

In some examples of the system, each primary power switch circuit includes a first power switch coupled to an input power supply signal and an output power supply signal. Each primary power switch further includes a first set of devices configured to: turn on the first power switch in response to the first control signal; provide the first control signal to a next secondary power switch circuit; turn on or turn off the first power switch based on the second control signal; and provide the second control signal to the next secondary power switch circuit.

In some examples of the system, each secondary power switch circuit includes a second power switch coupled to the input power supply signal and the output power supply signal. Each secondary power switch circuit further includes a second set of devices configured to: turn on the second power switch in response to the first control signal; provide the first control signal to a following secondary power switch circuit; turn on or turn off the second power switch based on the second control signal; and provide the second control signal to the following secondary power switch circuit.

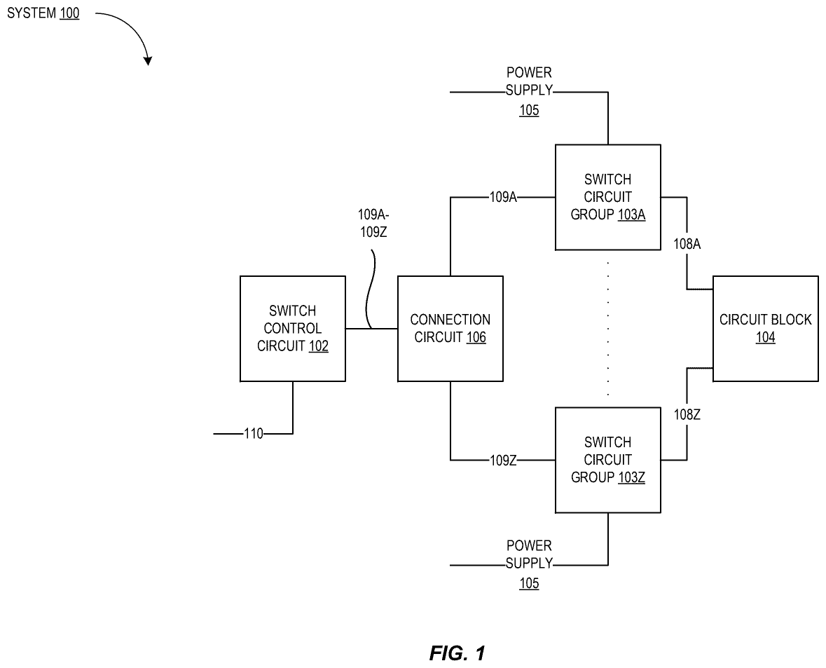

FIG. 1 illustrates a diagram of an example system 100, in accordance with one or more embodiments of the present disclosure. The system 100 includes switch control circuit 102, connection circuit 106, switch circuit groups 103A to 103Z, and circuit block 104.

In one embodiment, circuit block 104 may include any suitable combination of circuits, modules, components, devices, etc., configured to perform a particular function. For example, in some embodiments, a particular circuit block 104 may include a processor or processor core. In another example, circuit block 104 may include a camera sensor/module. Alternatively, in other embodiments, circuit block 104 may include multiple data storage cells, row and column decoders, and other circuitry associated with a memory circuit.

Switch circuit groups 103A to 103Z are coupled to power supply 105 (e.g., an input power supply), respectively, which are, in turn, coupled to one or more power supply terminals (not illustrated in FIG. 1) of circuit block 104, respectively. In one embodiment, the switch circuit groups 103A to 103Z may limit, control, change, etc., an amount of current that may flow from power supply 105 to output power supplies 108A to 108Z (e.g., a local power supply) respectively based on control signals 109A to 109Z, respectively (e.g., based on voltage levels of control signals 109A to 109Z). In some examples, output power supplies 108A to 108Z may be a single output power supply signal provided by the switch circuit groups 103A to 103Z to the circuit block 104. Although switch circuit groups 103A to 103Z are illustrated as being coupled to power supply 105, one or more of the switch circuit groups 103A to 103Z may be coupled to other power supplies in other embodiments (e.g., switch circuit group 103A may be coupled to a first power supply and switch circuit group 103Z may be coupled to a second power supply).

In one embodiment, switch control circuit 102 may be any suitable combination of circuits, modules, components, devices, etc., for generating control signals 109A to 109Z. As described below in more detail, switch control circuit 102 may generate control signals 109A to 109Z based on request signal 110. The request signal 110 may be received from (and/or generated by) a processor, power management circuit, or any other suitable circuit, device, component, etc. In some embodiments, the request signal 110 may indicate a request for a target voltage and/or amount of power/current. Based on the request signal, switch control circuit 102 may turn on/off one or more of switch circuit groups 103A to 103Z to provide power/current to the circuit block 104. In certain embodiments, switch control circuit 102 may turn on/off individual components of switch circuit groups 103A to 103Z using control signals 109A to 109Z.

Connection circuit 106 may include any suitable combination of circuits, modules, components, devices, etc., for providing, transmitting, sending, etc., signals (e.g., control signals) to switch circuit groups 103A to 103Z. For example, connection circuit 106 may include one or more multiplexers, buffers, etc., that may be used for routing the control signals 109A to 109Z to switch circuit groups 103A to 103Z, and for routing signals output by one switch circuit group to an input of a next switch circuit group.

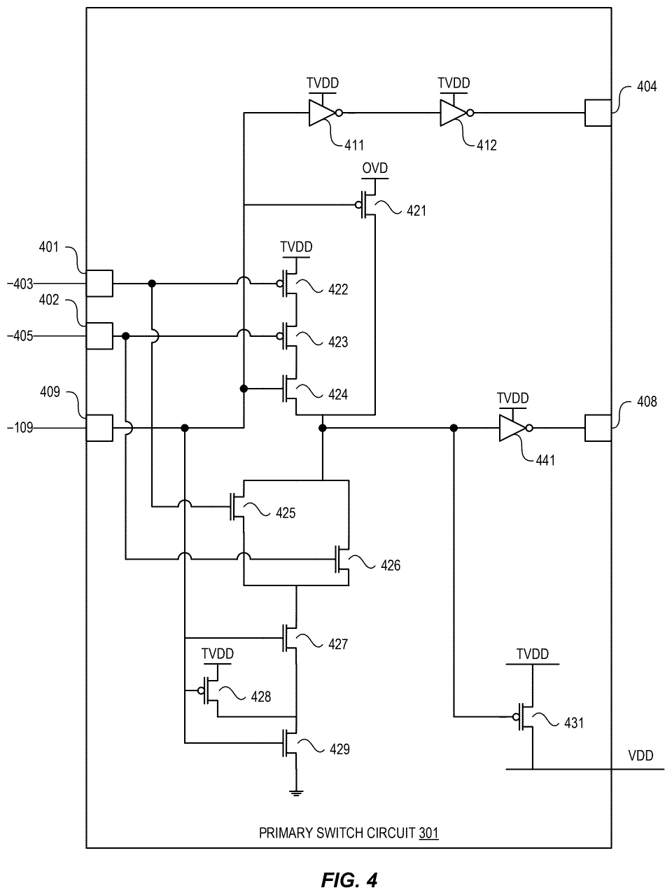

In one embodiment, each of the control signals 109A through 109Z may include multiple signals (e.g., multiple control signals, multiple sub-control signals, etc.) For example, referring to FIG. 4, control signal 109A may include three control signals, including a first control signal provided to input node 401, a second control signal provided to input node 402, and a third control signal provided to input node 409. Based on the values (e.g., voltage levels) of the control signals received at the different input nodes, the switch circuits may operate in different modes of operation as discussed in more detail below. Control signals in addition to the control signal 109A may be provided to the switch circuit group 103A. For example, referring to FIG. 4, control signals 109, 403, and 405 may be provided to primary switch circuit 301.

An exemplary advantage of an embodiment is that the switch circuit groups 103A to 103Z may allow for a reduction in the number of traces, connections, wires, etc., that are used to control, manage, and/or communicate with the individual switch circuits in the switch circuit groups 103A to 103Z. For example, the connection circuit 106 may route signals to a primary switch circuit in the switch circuit groups 103A to 103Z. The primary switch circuit may forward the signals to the next secondary switch circuit, which may also forward the signals to the next secondary switch circuit, and so on. By providing control signals directly to the primary switch circuit (instead of all the switch circuits), and configuring the switch circuits to forward control signals to other switch circuits, the number of traces, connections, wires, etc., may be reduced.

In addition, the switch circuit groups 103A to 103Z may be able to operate in multiple modes of operation. For example, receiving control signals at different input nodes/ports may indicate the mode of operation to a primary switch circuit. In a first mode of operation (during a boot/power up) indicated by a first control signal, the switch circuit groups 103A to 103Z may initialize serially (e.g., one switch circuit group at a time, and one switch circuit at a time). This may prevent potential high in-rush currents. In a second mode of operation (e.g., a voltage regulation mode) indicated by a second control signal, the switch circuit groups 103A to 103Z may be controlled (e.g., selected switch circuit groups may be concurrently turned and unselected switch circuit groups may be concurrently turned off, with the selection varying over time) using control signals transmitted to the primary switch circuits of the switch circuit groups 103A to 103Z to provide a regulated output voltage. The switch circuits in the switch circuit groups may forward the second signal through to the other switch circuits in the switch circuit group, reducing the need for signals, traces, wires, etc.

In a third mode of operation (e.g., a panic or emergency mode) indicated by a third control signal, the switch circuit groups 103A to 103Z may all be turned on simultaneously to provide more power to the circuit block 104. In a fourth mode of operation indicated by a fourth control signal, the gates of the power switches in the switch circuit groups 103A to 103Z may be provided with a higher voltage level (e.g., may be overdriven) to reduce leakage through the power switches.

In one embodiment, the switch circuit groups 103A to 103Z may provide the functionality/modes of operations discussed herein while maintaining a low circuit area profile (e.g., occupying a smaller area on a die).

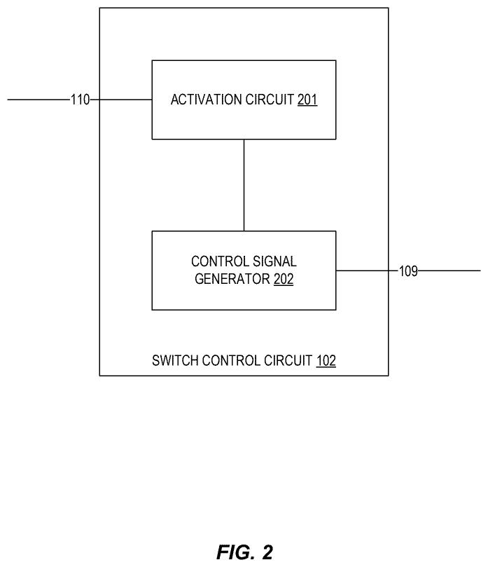

FIG. 2 illustrates a diagram of an example switch control circuit 102, in accordance with one or more embodiments of the present disclosure. Switch control circuit 102 includes activation circuit 201 and a control signal generator 202.

In one embodiment, activation circuit 201 may include any suitable combination of circuits (e.g., logic circuits/circuitry), components, devices, etc., configured to control the control signal generator 202. For example, the activation circuit 201 may provide signals to the control signal generator 202 to control various components, circuits, devices, etc., of the control signal generator 202. The activation circuit 201 may activate control signal generator 202 based on request signal 110.

Control signal generator 202 may be configured to generate control signal 109. Control signal 109 may represent control signals 109A through 109Z illustrated in FIG. 1 (e.g., control signal 109 may represent and/or include multiple control signals). In some cases, control signal generator 202 may include charge pumps, boost circuits, or other circuits suitable for generating a voltage level on control signal 109 greater than a global power supply voltage, or less than a ground potential.

In one embodiment, the activation circuit 201 may determine which switch circuit groups 103A to 103Z should be turned on/off based on a target voltage and/or a target current and request signal 110. Request signal 110 may indicate that the switch circuit groups 103A to 103Z should be operating in one of a variety of modes and may also indicate a target voltage for the switch circuit groups 103A to 103Z. The activation circuit 201 may include logic to decode the request signal 110. As an example, the request signal 110 may indicate that the switch circuit groups 103A to 103Z should be operating in a fast low-dropout voltage regulation mode to supply a regulated voltage at a target voltage level. In such an example, the activation circuit 201 may decode the request signal 110 to identify the particular mode and continually compare (through the use of a comparator or other logic, for example) the present output voltage to the target voltage. Based on the difference between the present output voltage and the target voltage, the activation circuit 201 may be configured to select a particular number of the switch circuit groups 103A to 103Z to currently be used in the voltage regulation mode, and send one or more signals to control signal generator 202 for generating and sending the control signals to turn on the selected ones of the switch circuit groups 103A to 103Z and turn off the unselected ones of the switch circuit groups 103A to 103Z.

For example, if a circuit block 104 uses a certain amount of power, the activation circuit 201 may determine which ones of switch circuit groups 103A through 103Z should be used to meet the target voltage/current, and which switch circuit groups 103A through 103Z should be turned off. For example, the activation circuit 201 may use certain control codes to identify which ones of switch circuit groups 103A through 103Z should be turned on or turned off to meet the target voltage/current. Each control code may be associated with a particular amount of power and/or may be associated with a particular set of the switch circuit groups 103A through 103Z to provide the particular amount of power. The control code may be provided to the connection circuit 106 and based on the control code, the connection circuit 106 may provide control signals to the particular set of the switch circuit groups 103A through 103Z. Alternatively, the activation circuit 201 may identify the particular set of the switch circuit groups 103A through 103Z for the control code, and a control signal may be sent to each of the switch circuit groups 103A through 103Z.

In some examples, system 100 provides digitally adaptive power switching. During the voltage regulation mode, the activation circuit 201 may continually compare (e.g., at each clock cycle) the present output voltage from the switch circuit groups 103A to 103Z to the target voltage, and based on the difference, the activation circuit 201 may continually (e.g., at each clock cycle) update the switch circuit groups 103A to 103Z to currently be used in the voltage regulation mode. The activation circuit 201 may make a determination in each phase (e.g., clock cycle), based on the comparison, regarding the optimum set of switch circuit groups 103A to 103Z to be on in a next phase (e.g., clock cycle). In the voltage regulation mode, the switch control circuit 102 may repeatedly send control signals to cause selected switch circuit groups to turn on (or remain on) and unselected switch circuit groups 103A to 103Z to turn off (or remain off) to generate a regulated output voltage at the target voltage level.

In some examples, the strength (e.g., amount or level of current being output) of the switch circuit groups 103A to 103Z varies in a binary manner. For example, if a strength of switch circuit group 103A is S, the strength of the next switch circuit group is 2*S, the strength of the switch circuit group after that is 4*S, and the strength of the final switch circuit group (e.g., 103Z) may be 128*S. In other examples, the strength of the final switch circuit group may be higher or lower than 128*S.

In some examples, the activation circuit 201 may use a clock cycle frequency of 200 MHz or higher. For a clock cycle frequency of 200 MHz, the activation circuit 201 may make a comparison of the current output voltage and the target output voltage, and make a strength adjustment (e.g., a selection of which of the switch circuit groups 103A to 103Z are to be on, and which of the switch circuit groups 103A to 103Z are to be off, in the next clock cycle) based on the comparison in discrete time steps every 5 ns.

Although various circuits, devices, components, etc., are illustrated in FIG. 2, different circuit blocks and different arrangements of circuit blocks are possible and contemplated in other embodiments.

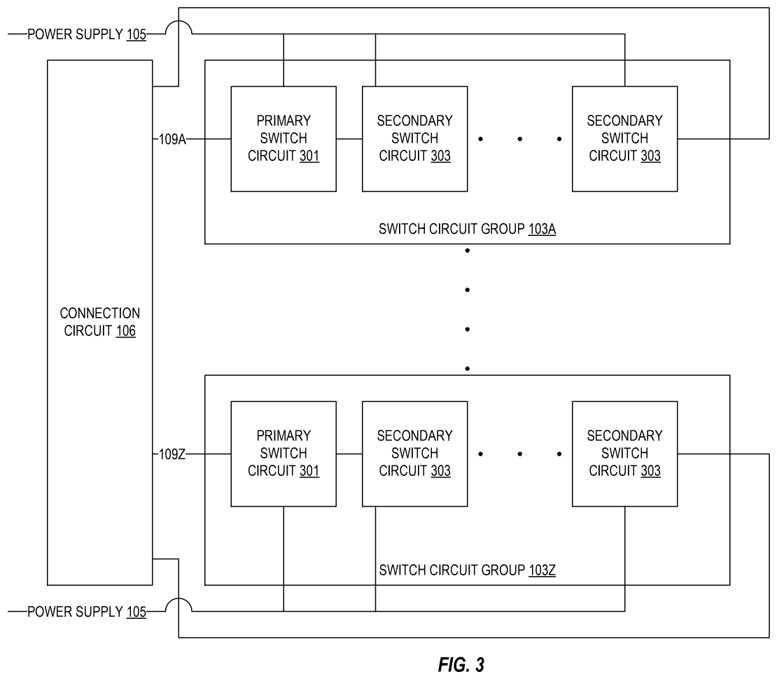

FIG. 3 illustrates a diagram of example switch circuit groups 103A to 103Z, in accordance with one or more embodiments of the present disclosure. As discussed above, switch circuit groups 103A to 103Z are coupled to power supply 105 (e.g., an input power supply). The switch circuit groups 103A to 103Z may provide current/power from the power supply 105 to a circuit block (e.g., circuit block 104 illustrated in FIG. 1). The switch circuit groups 103A to 103Z may limit, control, change, etc., an amount of current that may flow from power supply 105 to one or more output supply signals (e.g., output power supplies 108A to 108Z) based on control signals 109A to 109Z (e.g., based on voltage levels of control signals 109A to 109Z).

As illustrated in FIG. 3, each of switch circuit groups 103A through 103Z includes a primary switch circuit 301 and one or more secondary switch circuits 303. The primary switch circuit 301 and secondary switch circuits 303 for a switch group are coupled serially and/or in series. For example, for switch circuit group 103A, primary switch circuit 301 is coupled to a secondary switch circuit 303, which is coupled to a next secondary switch circuit 303, etc. The connection circuit 106 may provide the control signals (e.g., control signals 109) generated by the switch control circuit 102 to the primary switch circuit 301 in each switch circuit group. The primary switch circuit 301 may forward the control signals to a next secondary switch circuit 303, which may forward the control signals to a next secondary switch circuit 303, etc. In one embodiment, when the control signals reach the end of a switch circuit group (e.g., reaches the last secondary switch circuit in a switch circuit group), the control signal may be provided from that last secondary switch circuit in the switch circuit group to a next switch circuit group (e.g., to the primary switch circuit 301 of the next switch circuit group).

In one embodiment, the primary switch circuit 301 may be referred to as a controller, a leader, etc. For example, the primary switch circuit 301 may receive control signals from the switch control circuit 102 and may perform the task of forwarding the control signals to the secondary switch circuits 303 in a switch circuit group.

Each primary switch circuit 301 and secondary switch circuit 303 in a switch circuit group may be coupled to an input power supply for the switch circuit group, such as power supply 105. The primary switch circuit 301 and the secondary switch circuits 303 (for a switch circuit group) may also be coupled to an output power supply (e.g., the primary switch circuit 301 and the secondary switch circuits 303 for a switch circuit group may be coupled to the same output power supply). Referring to FIG. 1, each circuit group 103A through 103Z may limit, control, change, etc., an amount of current that may flow from power supply 105 to one or more output power supplies (e.g., output power supplies 108A to 108Z), based on control signals 109A to 109Z.

As discussed above, connection circuit 106 may include any suitable combination of circuits, modules, components, devices, etc., for providing, transmitting, sending, etc., signals (e.g., signals) to switch circuit groups 103A to 103Z. For example, connection circuit 106 may include one or more multiplexers, buffers, etc., that may be used to route the control signals 109A to 109Z to switch circuit groups 103A to 103Z. As discussed above, a switch control circuit (e.g., switch control circuit 102 illustrated in FIG. 1) may generate various control signals. The connection circuit 106 may route various control signals to appropriate ones of the switch circuit groups 103A to 103Z.

In one embodiment, a first control signal (e.g., a first type of control signal, a first set of multiple control signals, etc.) may be used to initialize the switch circuit groups 103A to 103Z. As discussed above, during boot up or power up of the system 100, all the switch circuits may be initialized (e.g., power switches turned on) so that the switch circuits may begin to provide current to the circuit block 104. However, it may not be beneficial for all the switch circuits to initialize at the same time. For example, the first control signal may be used to initialize, setup, etc., the switch circuits in the switch circuit groups 103A to 103Z. The first control signal may be used to initialize the switch circuit groups 103A to 103Z serially (e.g., in a serial order), including initializing the switch circuits in the switch circuit groups 103A to 103Z serially (e.g., in a serial order).

The first control signal may be used to turn on the primary switch circuit 301 and the remaining secondary switch circuits 303 in switch circuit group 103A in serial order (e.g., from right to left). For example, if the first control signal has a value of one or logical high, this may indicate that the primary switch circuit 301 should initialize. The primary switch circuit 301 may then forward the first control signal to the next secondary switch circuit 303, which will forward the first control signal to the next secondary switch circuit 303, and so on. After all of the switch circuits in the switch circuit group 103A are initialized, the first control signal may be provided to a next switch circuit group (e.g., from the last secondary switch circuit 303 in switch circuit group 103A to the primary switch circuit 301 in the next switch circuit group). The switch circuits in that next switch circuit group may be initialized serially (e.g., from right to left) and so on, until the switch circuits in switch circuit group 103Z are initialized. This may help prevent or reduce potential high in-rush currents. In one embodiment, the primary switch circuit 301 of a switch circuit group may determine that the switches in the group should be initialized based on the values of control signals provided to different input nodes of the primary switch circuit 301.

In one embodiment, a second control signal (e.g., a second type of control signal) may be used to turn on (or cause to remain on) selected ones of the switch circuit groups 103A to 103Z and turn off (or cause to remain off) unselected ones of the switch circuit groups 103A to 103Z to provide a regulated output voltage. The second control signal may be used to turn on power switches in the switch circuits of particular switch circuit groups, as discussed in more detail below. For example, the connection circuit 106 may route, forward, transmit, etc., the second control signal to one or more of the switch circuit groups 103A to 103Z, based on an amount of current/power requested, needed, and/or used by a circuit block (e.g., circuit block 104). For example, the switch control circuit 102 may identify five switch circuit groups that should be used for voltage regulation. The switch control circuit 102 may generate the second control signal and may forward the second control signal to the appropriate inputs on the connection circuit 106 (e.g., each input on the connection circuit 106 may correspond to a particular switch circuit group). The connection circuit 106 may send the second control signal to the primary switch circuits of the five switch circuit groups (e.g., may turn on the five switch circuit groups). Each primary switch circuit in a switch circuit group may forward the control signal to other secondary switch circuits in the same switch circuit group.

In one embodiment, a third control signal (e.g., a third type of control signal) may be used to turn on all the switch circuit groups 103A to 103Z. For example, if the switch control circuit 102 determines that the circuit block 104 needs a larger amount of power/current, the switch control circuit 102 may determine that all (or a threshold number) of the switch circuit groups 103A through 103Z should be turned on. The switch control circuit 102 may use the connection circuit 106 to transmit the third control signal to all the switch circuit groups 103A to 103Z simultaneously (or close to simultaneously).

In one embodiment, a fourth control signal (e.g., a fourth type of control signal) may be used to reduce current leakage through the switch circuit groups 103A to 103Z. For example, the fourth control signal may cause the gate of a power switch of each of the switch circuit groups 103A to 103Z to be coupled to power supply (e.g., an overdrive power supply signal or OVD) that has a higher voltage level than the voltage level of the power supply 105. This may help prevent and/or reduce current leakage through the switch circuit groups 103A to 103Z (e.g., through power switches or FETs of the switch circuit groups 103A to 103Z).

FIG. 4 illustrates a diagram of an example primary switch circuit 301, in accordance with one or more embodiments of the present disclosure. As discussed above, the primary switch circuit 301 may be part of a switch circuit group (e.g., a group of switch circuits, such as switch circuit group 103A to 103Z illustrated in FIG. 1, etc.). The primary switch circuit 301 includes input nodes 401, 402, and 409, and output nodes 404 and 408. The primary switch circuit 301 also includes devices 421 to 429, and 431. The primary switch circuit 301 further includes inverters 411, 412, and 441. Device 431 may be referred to herein as a power switch device or power switch.

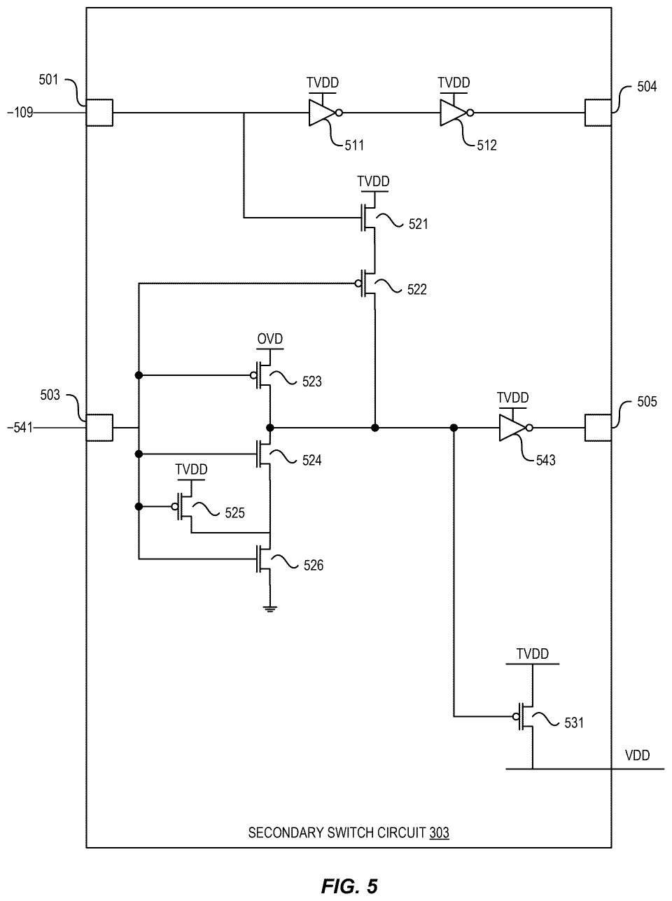

In one embodiment, inverters 411 and 412 may operate or act as a buffer for control signal 109. The control signal 109 may be inverted by inverter 411 and inverted again by inverter 412 before providing the control signal 109 to output node 404. The output node 404 is coupled to an input node (e.g., input node 501 illustrated in FIG. 5) of a next secondary switch circuit 303 in the switch circuit group.

In one embodiment, the inverter 441 may invert the signal/voltage used to control the gate of device 431. For example, if the gate of device 431 receives a high signal/voltage, the inverter 441 may invert the high signal/voltage to a low signal/voltage and provide the inverted signal/voltage to the output node 408. In another example, if the gate of device 431 receives a low signal/voltage, the inverter 441 may invert the low signal/voltage to a high signal/voltage and provide the inverted signal/voltage to the output node 408.

In one embodiment, devices 421 to 429 and 431 may be field-effect transistors (FETS). For example, devices 421 to 429 and 431 may be metal-oxide-semiconductor field-effect transistors (MOSFETS). Devices 421, 422, 423, 428, and 431 may be p-channel MOSFETs (e.g., a pFET, a pMOSFET, etc.). Devices 424, 425, 426, 427, and 429 may be n-channel MOSFETs (e.g., a nFET, a nMOSFET, etc.).

In one embodiment, the primary switch circuit 301 may receive control signal 109 via input node 409. The control signal 109 may be a first control signal that may enable, initialize, etc., the primary switch circuit 301. For example, when the control signal 109 is high (e.g., a higher voltage level, a logical 1, etc.), the primary switch circuit 301 may be operational, and may use other control signals (e.g., control signal 403 and 405 discussed below) to couple an input power supply (e.g., TVDD) to an output power supply (e.g., VDD). The control signal 109 is provided to inverter 411, device 421, device 424, device 427, device 428, and device 429.

In one embodiment, the primary switch circuit 301 may also receive control signal 405 via input node 402. The control signal 405 may be a second control signal that may be used to turn device 431 on and off to allow the switch circuit group to limit, control, change, etc., an amount of current that may flow from an input power supply (e.g., TVDD) to an output power supply (e.g., VDD). For example, the second control signal may be used to control devices in the primary switch circuit 301 (e.g., device 431) to allow a power supply signal from TVDD to go to VDD (e.g., to a circuit block, such as circuit block 104 illustrated in FIG. 1), or to allow the power supply signal from TVDD to be regulated down to a lower voltage that goes to VDD and is supplied to the circuit block 104.

In one embodiment, the primary switch circuit 301 may also receive control signal 403 via input node 401. The control signal 403 may be a third control signal that is used to turn on the device 431 and other devices in other switch circuits (e.g., other primary switch circuits 301 and other secondary switch circuits 303). For example, all of the primary switch circuits 301 and secondary switch circuits 303 may be turned on based on the control signal 403.

In one embodiment, the control signal 109 may transition from low to high (e.g., transition from a logical 0 to a logical 1), control signal 403 may be high (e.g., a logical 1), and control signal 405 may be high (e.g., a logical 1). When control signals 403 and 405 are high, and control signal 109 transition from low to high, this may initialize, etc., the primary switch circuit 301. Primary switch circuit 301 may be operating in a first mode of operation (e.g., an initialization mode). For example, this may turn off devices 421, 422, 423, and 428, and may turn on devices 424, 425, 426, 427, and 429. Because device 426, 427, and 429 are turned on, the voltage level at the gate of device 431 may be at or near ground potential. This may turn on the device 431 to allow current to flow from input power supply TVDD to output power supply VDD. Once the primary switch circuit 301 initializes, the control signal 403 may transition from high to low.

In one embodiment, the control signal 109 may be high (e.g., a logical 1), control signal 403 may be low (e.g., a logical 0), and control signal 405 may be high (e.g., a logical 1). When the control signal 109 is high and the control signal 403 is low, the primary switch circuit 301 may be operating in a second mode of operation (e.g., a voltage regulation mode) where the device 431 is controlled based on control signal 405. When the control signal 109 is high, the devices 421 and 428 may be turned off (e.g., may not allow current to flow) and devices 424, 427, and 429 may be turned on (e.g., may allow current to flow). When the control signal 403 is low, device 422 may be turned on and device 425 may be turned off. When the control signal 405 is high, device 423 may be turned off and device 426 may be turned on. Because device 426, 427, and 429 are turned on, the voltage level at the gate of device 431 may be at or near ground potential. This may turn on the device 431 to allow current to flow from input power supply TVDD to output power supply VDD.

In one embodiment, the control signal 109 may be high (e.g., a logical 1), control signal 403 may be low (e.g., a logical 0), and control signal 405 may be low (e.g., a logical 0). When the control signal 109 is high and the control signal 403 is low, the primary switch circuit 301 may be operating in the second mode of operation (e.g., a voltage regulation mode) where the device 431 is controlled based on control signal 405. When the control signal 109 is high, the devices 421 and 428 may be turned off (e.g., may not allow current to flow) and devices 424, 427, and 429 may be turned on (e.g., may allow current to flow). When the control signal 403 is low, device 422 may be turned on and device 425 may be turned off. When the control signal 405 is low, device 423 may be turned on and device 426 may be turned off. Because devices 422, 423, 424 are turned on and devices 425 and 426 are turned off, the voltage level at the gate of device 431 may be at or near the level of input power supply TVDD. This may turn off the device 431 to prevent current from flowing from input power supply TVDD to output power supply VDD.

As discussed above, when the control signal 109 is high and the control signal 403 is low, the primary switch circuit 301 may be operating in a second mode of operation (e.g., a voltage regulation mode) where the device 431 is controlled based on control signal 405. In one embodiment, the control signal 403 may transition from low to high and control signal 109 may remain high. When the control signal 403 transitions from low to high, the primary switch circuit 301 may be operating in a third mode of operation (e.g., an emergency mode of operation, an emergency operating mode, a panic mode, etc.) where the device 431 will allow current to flow regardless of control signal 405. The primary switch circuit 301 may operate in the third mode of operation when the switch control circuit 102 determines that a circuit block 104 has a more immediate demand for power/current. When control signal 403 transitions from low to high, this may turn off device 422 and may turn on device 425. Devices 427 and 429 may be turned on because control signal 109 is high. Because devices 425, 427, and 429 are turned on, the voltage level at the gate of device 431 may be at or near ground potential, regardless of the voltage level of control signal 405 (e.g., regardless of whether device 426 is on or off). This may turn on the device 431 to allow current to flow from input power supply TVDD to output power supply VDD. Turning on device 431 may also turn on the remaining power switches in the secondary switch circuits of a switch group via the output nodes 408 and 505 (e.g., via the signals output by output nodes 408 and 505). In one embodiment, when the control signal 403 transitions from low to high, the control signal 403 may be provided to multiple switch circuit groups simultaneously. For example, the control signal 403 may be provided to the primary switch circuit 301 of each switch circuit group.

In one embodiment, the control signal 109 may be transition from high to low (e.g., transition from a logical 1 to a logical 0), control signal 403 may be high (e.g., a logical 1), and control signal 405 may be high (e.g., a logical 1). When control signals 403 and 405 are high, and control signal 109 transitions from high to low, this may deactivate, shut off, etc., the primary switch circuit 301 (e.g., may indicate that the primary switch circuit 301 should operate in the fourth mode of operation). The primary switch circuit 301 may be in the fourth mode of operation (e.g., an inactive mode, a deactivated mode, a low power mode, a low leakage mode, etc.) when control signals 403 and 405 are high, and control signal 109 is low. For example, this may turn off devices 422, 423, 424, 427, and 429, and may turn on devices 421 and 428. Because device 421 is turned on, the voltage level at the gate of device 431 may be brought to the voltage level of power supply OVD. The voltage of power supply OVD may be greater than the voltage level of power supply TVDD. This may turn off the device 431 and prevent current from flowing through device 431 and may also reduce the amount of leakage current that flows through the device 431.

It is noted that, to improve clarity and to aid in demonstrating the disclosed concepts, the block diagram illustrated in FIG. 4 has been simplified. In other embodiments, different and/or additional circuits, devices, components, elements, etc., are possible and contemplated.

FIG. 5 illustrates a diagram of an example secondary switch circuit 303, in accordance with one or more embodiments of the present disclosure. As discussed above, the secondary switch circuit 303 may be part of a switch circuit group (e.g., a group of switch circuits, such as switch circuit group 103A to 103Z illustrated in FIG. 1, etc.). The secondary switch circuit 303 includes input nodes 501 and 503, and output nodes 504 and 505. In an example, input nodes 501 and 503 are coupled to output nodes 404 and 408, respectively, of primary switch circuit 301 when the secondary switch circuit 303 immediately follows the primary switch circuit 301 in a switch circuit group, and input nodes 501 and 503 are coupled to output nodes 504 and 505, respectively, of another secondary switch circuit 303 when the secondary switch circuit 303 immediately follows the other secondary switch circuit 303 in the switch circuit group. The secondary switch circuit 303 also includes devices 521 to 526 and 531. The secondary switch circuit 303 further includes inverters 511, 512, and 543. Device 531 may be referred to herein as a power switch device or power switch.

In one embodiment, inverters 511 and 512 may operate or act as a buffer for control signal 109. The control signal 109 may be inverted by inverter 511 and inverted again by inverter 512 before providing the control signal 109 to output node 504. The output node 504 is coupled to an input node (e.g., input node 501 of a next secondary switch circuit 303 in the switch circuit group).

In one embodiment, the inverter 543 may invert the signal/voltage used to control the gate of device 531. For example, if the gate of device 531 receives a high signal/voltage, the inverter 543 may invert the high signal/voltage to a low signal/voltage and provide the inverted signal/voltage to the output node 505. In another example, if the gate of device 531 receives a low signal/voltage, the inverter 543 may invert the low signal/voltage to a high signal/voltage and provide the inverted signal/voltage to the output node 505.

In one embodiment, devices 521 to 526 and 531 may be field-effect transistors (FETS). For example, devices 521 to 526 and 531 may be metal-oxide-semiconductor field-effect transistors (MOSFETS). Devices 522, 523, 525, and 531 may be p-channel MOSFETs (e.g., a pFET, a pMOSFET, etc.). Devices 521, 524, and 526 may be n-channel MOSFETs (e.g., a nFET, a nMOSFET, etc.).

In one embodiment, the secondary switch circuit 303 may receive control signal 109 via input node 501. The control signal 109 may be a first control signal that may enable, initialize, etc., the secondary switch circuit 303. Secondary switch circuit 303 may be operating in a first mode of operation (e.g., an initialization mode). For example, when the control signal 109 is high (e.g., a higher voltage level, a logical 1, etc.), the secondary switch circuit 303 may be operational, and may use other control signals (e.g., control signal 541 discussed below) to couple an input power supply (e.g., TVDD) to an output power supply (e.g., VDD). The control signal 109 is provided to inverter 511 and device 521.

In one embodiment, the secondary switch circuit 303 may also receive control signal 541 via input node 503. The control signal 541 may be a second control signal that may be used to turn device 531 on and off to allow the switch circuit group to limit, control, change, etc., an amount of current that may flow from an input power supply (e.g., TVDD) to an output power supply (e.g., VDD). For example, the second control signal may be used to control devices in the secondary switch circuit 303 (e.g., device 531) to allow a power supply signal from TVDD to go to VDD (e.g., to a circuit block, such as circuit block 104 illustrated in FIG. 1). The control signal 541 may also be used to turn other devices in other switch circuits (e.g., other secondary switch circuits 303) on and off. For example, different voltage levels may be provided to the gate of device 531 based on the control signal 541. Those voltage levels or signals (provided to the gate of device 531) may be provided to other secondary switch circuits 303 via inverter 543 and output node 505.

In one embodiment, the control signal 109 may be high (e.g., a logical 1) and control signal 541 may be high (e.g., a logical 1). When the control signal 109 is high and the control signal 541 is high, the secondary switch circuit 303 may be operating in a second mode of operation (e.g., a voltage regulation mode) where the device 531 is controlled based on control signal 541. When the control signal 109 is high, the device 521 may be turned on. When the control signal 541 is high, devices 524 and 526 may be turned on and devices 522, 523, and 525 may be turned off. Because devices 524 and 526 are turned on, the voltage level at the gate of device 531 may be at or near ground potential. This may turn on the device 531 to allow current to flow from input power supply TVDD to output power supply VDD.

In one embodiment, the control signal 109 may be high (e.g., a logical 1) and control signal 541 may be low (e.g., a logical 0). When the control signal 109 is high and the control signal 541 is low, the secondary switch circuit 303 may be operating in the second mode of operation (e.g., a voltage regulation mode) where the device 531 is controlled based on control signal 541. When the control signal 109 is high, the device 521 may be turned on. When the control signal 541 is low, devices 524 and 526 may be turned off and devices 522, 523, and 525 may be turned on. In the first mode of operation, the power supply OVD may be disabled or turned off. Because devices 521 and 522 are turned on, the voltage level at the gate of device 531 may be at or may be at or near the level of input power supply TVDD. This may turn off the device 531 to prevent current from flowing from input power supply TVDD to output power supply VDD.

In one embodiment, the secondary switch circuit 303 may operate in a third mode of operation (e.g., an emergency mode of operation, an emergency operating mode, a panic mode, etc.) where the signal 541 is held high (as long as signal 403 is high), causing device 531 to be on and allow current to flow.

In one embodiment, the secondary switch circuit 303 may operate in a fourth mode of operation (e.g., an inactive mode, a deactivated mode, a low leakage mode, etc.). When operating in the fourth mode of operation, the control signal 109 may be low and the control signal 541 may be low. Because device 521 is turned off and device 523 is turned on, the voltage level at the gate of device 531 may be at or near the level of input power supply OVD. The voltage level of power supply OVD may be greater than the voltage level of power supply TVDD. This may turn off the device 531 and prevent current from flowing through device 531 and may also reduce the amount of leakage current that flows through the device 531.

It is noted that, to improve clarity and to aid in demonstrating the disclosed concepts, the block diagram illustrated in FIG. 5 has been simplified. In other embodiments, different and/or additional circuits, devices, components, elements, etc., are possible and contemplated.

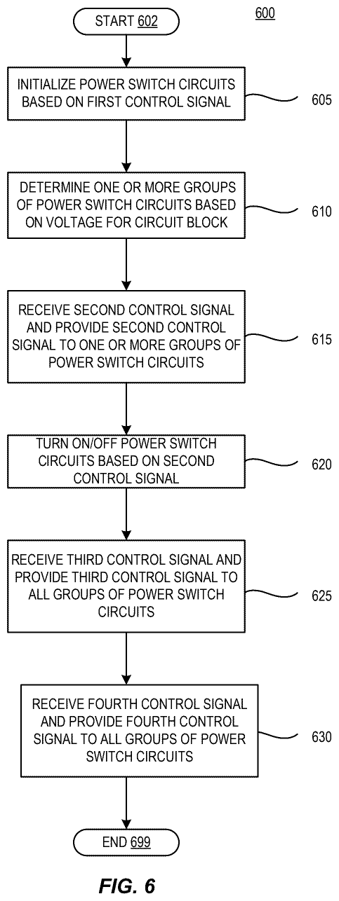

FIG. 6 illustrates a flow diagram depicting an embodiment of a method 600 for operating power switch circuits, in accordance with one or more embodiments of the present disclosure. The method 600, which may be applied to one or more of switch control circuit 102, connection circuit 106, switch circuit groups 103A-103Z, primary switch circuits 301, and secondary switch circuits 303, starts at the block 602.

The method 600 includes initializing power switch circuits based on a first control signal at block 605. The power switch circuits in method 600 may be organized into a plurality of switch circuit groups, with each switch circuit group including a primary power switch circuit and a set of secondary power switch circuits. The first control signal may be provided by a control circuit to the plurality of switch circuit groups in a serial order. The switch circuit groups may be initialized in a serial order and the power switch circuits within each switch circuit group may be initialized in a serial order.

At block 610, the method 600 includes determining one or more groups of power switch circuits to turn on and/or off, based on a target voltage for a circuit block. For example, a target voltage and/or target current for a circuit block may be determined based on a request received from the circuit block. For example, each group of power switch circuits may be able to provide a certain amount of power. The number of groups of power switch circuits may be determined based on a requested amount of power and the amount of power each group of power switch circuits can provide.

At block 615, the method 600 includes receiving a second control signal and providing the second control signal to the identified one or more groups of power switch circuits. At block 620, the power switch circuits of the identified groups may turn on or turn off based on the second control signal. The second control signal may be provided in parallel to the switch circuit groups, and selected ones of the switch circuit groups may be concurrently turned on and unselected ones of the switch circuit groups may be concurrently turned off based on the second control signal to generate a regulated output voltage. The selected ones of the switch circuit groups may vary over time based on a comparison of the regulated output voltage to a target voltage. Each of the switch circuit groups may output a substantially different amount of current than other ones of the switch circuit groups. The amount of current may approximately double from each one of the switch circuit groups to a next one of the switch circuit groups.

At block 625, the method 600 includes receiving a third control signal and providing the third control signal to all of the groups of power switch circuits. For example, the third control signal may indicate that a circuit block needs more power and that all of the power switch circuits should be turned on. Different FETS of the power switch circuits may be turned on/off to turn on all of the power switches of all of the power switch circuits. The third control signal may be provided by a control circuit to all of the switch circuit groups in parallel, and the plurality of switch circuit groups may all be concurrently turned on based on the third control signal.

At block 630, the method 600 includes receiving a fourth control signal and providing the fourth control signal to all the groups of power switch circuits. Based on the fourth control signal, gates of the power switches of the power switch circuits may be coupled to another power supply signal that has a voltage level greater than the input power supply signal used by the power switch circuits. As discussed above, this may help reduce current leakage. The method 600 of FIG. 6 ends at block 699.

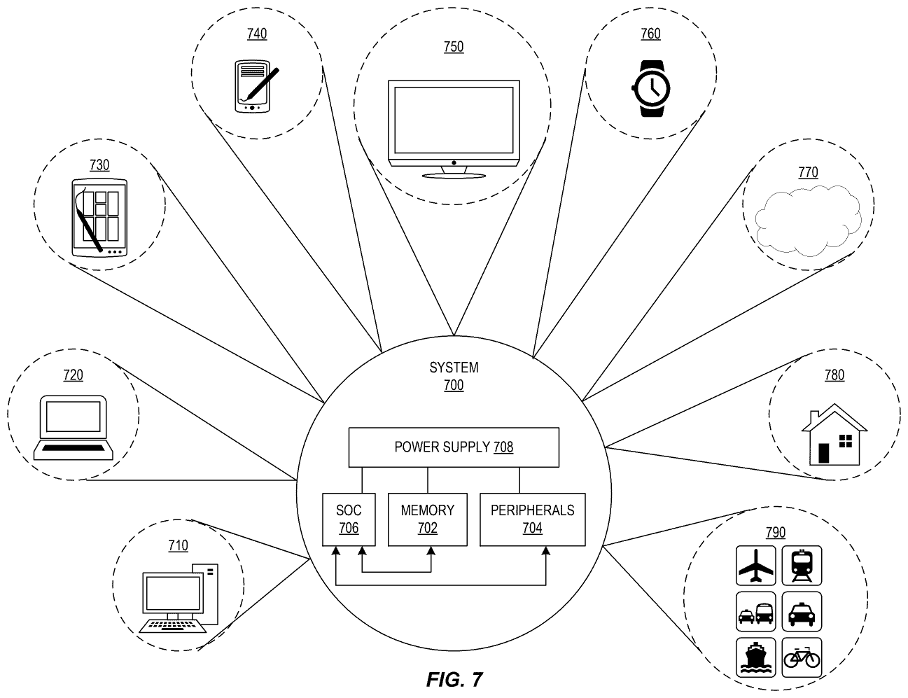

FIG. 7 illustrates a block diagram of an example system 700, in accordance with one or more embodiments of the present disclosure. The system 700 may incorporate and/or otherwise utilize the circuits, devices, components, methods, functions, and/or mechanisms described herein, including any or all of system 100 (FIG. 1). In the illustrated embodiment, the system 700 includes at least one instance of a system on chip (SoC) 706 which may include multiple types of processing units, such as a central processing unit (CPU), a graphics processing unit (GPU), or otherwise, a communication fabric, and interfaces to memories and input/output devices. In some embodiments, one or more processors in SoC 706 includes multiple execution lanes and an instruction issue queue. In various embodiments, SoC 706 is coupled to external memory 702, peripherals 704, and power supply 708. The system 700 may use plates (with regions and/or vias) that are coupled to various components (e.g., coupled to SoC 706).

Power supply 708 supplies the supply voltages to SoC 706 as well as one or more supply voltages to the memory 702 and/or the peripherals 704. In various embodiments, power supply 708 represents a battery (e.g., a rechargeable battery in a smart phone, laptop or tablet computer, or another device). In some embodiments, more than one instance of SoC 706 is included (and more than one external memory 702 may be included as well).

The memory 702 is any type of memory, such as dynamic random access memory (DRAM), synchronous DRAM (SDRAM), double data rate (DDR, DDR2, DDR3, etc.) SDRAM (including mobile versions of the SDRAMs such as mDDR3, etc., and/or low power versions of the SDRAMs such as LPDDR2, etc.), RAMBUS DRAM (RDRAM), static RAM (SRAM), etc. One or more memory devices are coupled onto a circuit board to form memory modules such as single inline memory modules (SIMMs), dual inline memory modules (DIMMs), etc. Alternatively, the devices are mounted with a SoC or an integrated circuit in a chip-on-chip configuration, a package-on-package configuration, or a multi-chip module configuration.

The peripherals 704 include any desired circuitry, depending on the type of system 700. For example, in one embodiment, peripherals 704 include devices for various types of wireless communication, such as Wi-Fi, Bluetooth, cellular, global positioning system, etc. In some embodiments, the peripherals 704 also include additional storage, including RAM storage, solid state storage, or disk storage. The peripherals 704 include user interface devices such as a display screen, including touch display screens or multitouch display screens, keyboard or other input devices, microphones, speakers, etc.

As illustrated, system 700 is shown to have application in a wide range of areas. For example, system 700 may be utilized as part of the chips, circuitry, components, etc., of a desktop computer 710, laptop computer 720, tablet computer 730, cellular or mobile phone 740, or television 750 (or set-top box coupled to a television). Also illustrated is a smartwatch and health monitoring device 760. In some embodiments, the smartwatch may include a variety of general-purpose computing related functions. For example, the smartwatch may provide access to email, cellphone service, a user calendar, and so on. In various embodiments, a health monitoring device may be a dedicated medical device or otherwise include dedicated health related functionality. For example, a health monitoring device may monitor a user's vital signs, track proximity of a user to other users for the purpose of epidemiological social distancing, contact tracing, provide communication to an emergency service in the event of a health crisis, and so on. In various embodiments, the above-mentioned smartwatch may or may not include some or any health monitoring related functions. Other wearable devices are contemplated as well, such as devices worn around the neck, devices that are implantable in the human body, glasses designed to provide an augmented and/or virtual reality experience, and so on.

System 700 may further be used as part of a cloud-based service(s) 770. For example, the previously mentioned devices, and/or other devices, may access computing resources in the cloud (i.e., remotely located hardware and/or software resources). Still further, system 700 may be utilized in one or more devices of a home 780 other than those previously mentioned. For example, appliances within the home may monitor and detect conditions that warrant attention. For example, various devices within the home (e.g., a refrigerator, a cooling system, etc.) may monitor the status of the device and provide an alert to the homeowner (or, for example, a repair facility) should a particular event be detected. Alternatively, a thermostat may monitor the temperature in the home and may automate adjustments to a heating/cooling system based on a history of responses to various conditions by the homeowner. Also illustrated in FIG. 7 is the application of system 700 to various modes of transportation 790. For example, system 700 may be used in the control and/or entertainment systems of aircraft, trains, buses, cars for hire, private automobiles, waterborne vessels from private boats to cruise liners, scooters (for rent or owned), and so on. In various cases, system 700 may be used to provide automated guidance (e.g., self-driving vehicles), general systems control, and otherwise. These and many other embodiments are possible and are contemplated. It is noted that the devices and applications illustrated in FIG. 7 are illustrative only and are not intended to be limiting. Other devices are possible and are contemplated.

The present disclosure includes references to “an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent claims that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality”of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or”is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some tasks even if the structure is not currently being operated. Thus, an entity described or recited as being “configured to” perform some tasks refers to something physical, such as a device, circuit, a system having a processor unit and a memory storing program instructions executable to implement the task, etc. This phrase is not used herein to refer to something intangible.

In some cases, various units/circuits/components may be described herein as performing a set of tasks or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

Various units, circuits, or other components may be described as “configured to” perform a task or tasks. In such contexts, “configured to” is a broad recitation of structure generally meaning “having circuitry that” performs the task or tasks during operation. As such, the unit/circuit/component can be configured to perform the task even when the unit/circuit/component is not currently on. In general, the circuitry that forms the structure corresponding to “configured to” may include hardware circuits. Similarly, various units/circuits/components may be described as performing a task or tasks, for convenience in the description. Such descriptions should be interpreted as including the phrase “configured to.” Reciting a unit/circuit/component that is configured to perform one or more tasks is expressly intended not to invoke 35 U.S.C. § 112, paragraph (f) interpretation for that unit/circuit/component. More generally, the recitation of any element is expressly intended not to invoke 35 U.S.C. § 112, paragraph (f) interpretation for that element unless the language “means for” or “step for” is specifically recited. Should Applicant wish to invoke Section 112(f) during prosecution of a United States patent application based on this disclosure, it will recite claim elements using the “means for”[performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements may be defined by the functions or operations that they are configured to implement. The arrangement and such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used to transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

Numerous variations and modifications will become apparent to those skilled in the art once the above disclosure is fully appreciated. It is intended that the following claims be interpreted to embrace all such variations and modifications.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. An apparatus, comprising:
a plurality of switch circuit groups, wherein each switch circuit group comprises a primary power switch circuit and a set of secondary power switch circuits; and
a connection circuit coupled to the plurality of switch circuit groups, the connection circuit configured to:
receive a first control signal from a control circuit and provide the first control signal to the plurality of switch circuit groups in a serial order, wherein the plurality of switch circuit groups is configured to initialize based on the first control signal; and
receive a second control signal from the control circuit and provide the second control signal in parallel to the switch circuit groups, wherein selected ones of the switch circuit groups are turned on and unselected ones of the switch circuit groups are turned off based on the second control signal.

2. The apparatus of claim 1, wherein the connection circuit is further configured to:
receive a third control signal from the control circuit and provide the third control signal to the plurality of switch circuit groups in parallel, wherein the plurality of switch circuit groups are all turned on based on the third control signal.

3. The apparatus of claim 2, wherein the connection circuit is further configured to:
receive a fourth control signal from the control circuit and provide the fourth control signal to the plurality of switch circuit groups, wherein an amount of current leakage through the plurality of switch circuit groups is reduced based on the fourth control signal.

4. The apparatus of claim 1, wherein each primary power switch circuit comprises:
a first power switch coupled to an input power supply signal and an output power supply signal; and
a first set of devices configured to:
turn on the first power switch in response to the first control signal;
provide the first control signal to a next secondary power switch circuit;
turn on or turn off the first power switch based on the second control signal; and
provide the second control signal to the next secondary power switch circuit.

5. The apparatus of claim 4, wherein each secondary power switch circuit comprises:
a second power switch coupled to the input power supply signal and the output power supply signal; and
a second set of devices configured to:
turn on the second power switch in response to the first control signal;
provide the first control signal to a following secondary power switch circuit;
turn on or turn off the second power switch based on the second control signal; and
provide the second control signal the following secondary power switch circuit.

6. The apparatus of claim 1, wherein the switch circuit groups are initialized in a serial order and the power switch circuits within each switch circuit group are initialized in a serial order.

7. The apparatus of claim 1, wherein
the plurality of switch groups is configured to generate a regulated output voltage; and
the selected ones of the switch circuit groups vary over time based on a comparison of the regulated output voltage to a target voltage.

8. The apparatus of claim 1, wherein each of the switch circuit groups outputs a substantially different amount of current than other ones of the switch circuit groups.

9. The apparatus of claim 8, wherein the amount of current approximately doubles from each one of the switch circuit groups to a next one of the switch circuit groups.

10. A method, comprising:
initializing, in response to a first control signal, a plurality of switch circuit groups, wherein the switch circuit groups are initialized in a serial order, and wherein each switch circuit group comprises a primary power switch circuit and a set of secondary power switch circuits; and
receiving a second control signal in parallel by the switch circuit groups, wherein selected ones of the switch circuit groups are turned on and unselected ones of the switch circuit groups are turned off based on the second control signal.

11. The method of claim 10, and further comprising:
receiving a third control signal by the plurality of switch circuit groups in parallel, wherein all the plurality of switch circuit groups are turned on based on the third control signal.

12. The method of claim 11, and further comprising:
receiving a fourth control signal by the plurality of switch circuit groups, wherein an amount of current leakage through the plurality of switch circuit groups is reduced based on the fourth control signal.

13. The method of claim 10, wherein initializing the plurality of switch circuit groups comprises:
initializing the switch circuit groups in a serial order; and
initializing the power switch circuits within each switch circuit group in a serial order.

14. The method of claim 10, further comprising generating, by the plurality of switch groups, a regulated output voltage, wherein the selected ones of the switch circuit groups vary over time based on a comparison of the regulated output voltage to a target voltage.

15. The method of claim 10, wherein each of the switch circuit groups outputs a substantially different amount of current than other ones of the switch circuit groups.

16. The method of claim 15, wherein the amount of current approximately doubles from each one of the switch circuit groups to a next one of the switch circuit groups.

17. A system, comprising:
a circuit block;
a switch control circuit;
a plurality of switch circuit groups coupled to the circuit block, wherein each switch circuit group comprises a primary power switch circuit and a set of secondary power switch circuits; and
a connection circuit coupled to the switch control circuit and the plurality of switch circuit groups, the connection circuit configured to:
receive a first control signal from the switch control circuit and provide the first control signal to the plurality of switch circuit groups in a serial order, wherein the plurality of switch circuit groups are configured to initialize based on the first control signal; and
receive a second control signal from the switch control circuit and provide the second control signal in parallel to the switch circuit groups, wherein selected ones of the switch circuit groups are turned on and unselected ones of the switch circuit groups are turned off based on the second control signal.

18. The system of claim 17, wherein the connection circuit is further configured to:
receive a third control signal from the switch control circuit and provide the third control signal to the plurality of switch circuit groups in parallel, wherein all the plurality of switch circuit groups are turned on based on the third control signal; and
receive a fourth control signal from the switch control circuit and provide the fourth control signal to the plurality of switch circuit groups, wherein an amount of current leakage through the plurality of switch circuit groups is reduced based on the fourth control signal.

19. The system of claim 17, wherein each primary power switch circuit comprises:
a first power switch coupled to an input power supply signal and an output power supply signal; and
a first set of devices configured to:
turn on the first power switch in response to the first control signal;
provide the first control signal to a next secondary power switch circuit;
turn on or turn off the first power switch based on the second control signal; and
provide the second control signal to the next secondary power switch circuit.

20. The system of claim 19, wherein each secondary power switch circuit comprises:
a second power switch coupled to the input power supply signal and the output power supply signal; and
a second set of devices configured to:
turn on the second power switch in response to the first control signal;
provide the first control signal to a following secondary power switch circuit;
turn on or turn off the second power switch based on the second control signal; and
provide the second control signal to the following secondary power switch circuit.
